(19) United States
(12) Patent Application Publication
(10) Pub. No.: US 2006/0006538 A1
(43) Pub. Date: Jan. 12, 2006

(54) Extreme low-K interconnect structure and method

(75) Inventors: Derryl D. J. Allman, Cames, WA (US); Charles E. May, Gresham, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 10/884,122

(22) Filed: Jul. 2, 2004

(51) Int. Cl. H01L 23/48

(52) U.S. Cl. 257/758

(57) ABSTRACT

Embodiments of the invention include an extreme low-K circuit structure formed on a substrate having a plurality of electrically conductive structures. A lattice structure of bracing material configured to support the electrically conductive structures is formed on the substrate and also can define regions of extreme low-K dielectric space between the electrically conductive structures. Additionally, methods for creating dielectric structures on a substrate are disclosed.

### TECHNICAL FIELD

The invention described herein relates generally to methods and structures used to form interconnect lines having high strength while still exhibiting extreme low-K dielectric properties between the interconnect lines.

### BACKGROUND

As integrated circuit (IC) design continues to evolve, one of the important barriers to improved IC performance is RC time delay. Such delay is induced, in part, by capacitance that exists between the various levels of electrical interconnects in an IC die. Although these problems are particularly evident in smaller circuit structures, such as IC's, they are also present in many other types of electrical circuit structures. Such RC delay problems are also experienced in printed circuit boards (PCB's). Conventional solutions to this problem have been the increasing reliant on highly conductive (lower resistance) interconnect materials such as copper. Also, insulating materials having increasingly lower dielectric constants have come into increasingly common usage in order to address this problem. For example, high carbon content oxide materials such as Black Diamond™ (available from Applied Materials) and CORAL™ (available from Novellus) are commonly used. Also, low-K organic materials such as Dow Corning's SiLK™ are used. Also, dielectric films are treated by various processes to increase their porosity (thereby lowering their dielectric constants (K)). These solutions are relatively effective at lowering the K values of the dielectric layers in which they are used. However, each of these films suffers from critical reductions in mechanical strength. These present low-K films are so mechanically weak that that resultant films are prone to cracking, collapse, shrinking, and moisture absorption. Also, in the case of the high carbon films, a laundry list of additional integration problems are also present. Examples include via poisoning, moisture retention (requiring additional baking to remove, voiding in the copper lines and vias, and copper migration through dielectric media.

Although the conventional implementations are useful for many applications, they place significant limitations on further electrical interconnect development due to the issues described above. Thus, there is a need for an improved approach in the generation of dielectric layers and structures used in conjunction with electrical interconnects and vias.

### SUMMARY OF THE INVENTION

In accordance with the principles of the present invention, improved methods and structures for establishing dielectric layers for electrical interconnections are disclosed.

In general, the present invention is directed toward a novel approach for creating dielectric structures on a substrate. In one embodiment an extreme low-K circuit structure is formed on a substrate having a plurality of electrically conductive structures. A lattice structure or bracing material configured to support the electrically conductive structures on the substrate is formed. The lattice structure defines regions of extreme low-K dielectric space between the electrically conductive structures.

Another embodiment of the invention describes methods for forming extreme low-K circuit structures. Typically the method involves providing a substrate and forming a layer of thermally evaporatable material on the substrate. The thermally evaporatable material is patterned to receive bracing material. A layer of bracing material is formed on portions of the substrate and on portions of the thermally evaporatable material. Electrically conductive structures are then formed on the bracing material. The thermally evaporatable material is removed to reveal a resulting lattice structure of bracing material that defines regions of low-K dielectric space between the plurality of electrically conductive structures.

Other aspects and advantages of the invention will become apparent from the following detailed description and accompanying drawings which illustrate, by way of example, the principles of the invention.

### BRIEF DESCRIPTION OF THE DRAWINGS

The following detailed description will be more readily understood in conjunction with the accompanying drawings, in which:

FIGS. 1-11 are simplified schematic cross section views of a portion of a substrate upon which a lattice of bracing material and electrical interconnect structures are formed in accordance with an embodiment of the invention.

FIG. 12A is simplified perspective view of a substrate embodiment having a plurality of electrical connections formed thereon and layers of thermal evaporation material also formed thereon.

FIG. 12B is simplified perspective view of a substrate embodiment such as that of FIG. 12A after processing to remove the thermal evaporation material leaving a lattice of bracing material that defines regions of extreme low-K.

FIG. 13 is simplified perspective view of a substrate embodiment having a plurality of “stacked” layers showing that the principles of the present invention can be used to construct multi-layer structures.

It is to be understood that in the drawings like reference numerals designate like structural elements. Also, it is understood that the depictions in the Figures are not necessarily to scale.

### DETAILED DESCRIPTION OF THE INVENTION

The present invention has been particularly shown and described with respect to certain embodiments and specific features thereof. The embodiments set forth hereinbelow are to be taken as illustrative rather than limiting. It should be readily apparent to those of ordinary skill in the art that various changes and modifications in form and detail may be made without departing from the spirit and scope of the invention.

In the following detailed description, fabrication methods and apparatus for constructing electrical conduction structures demonstrating extreme low-K properties will be disclosed.

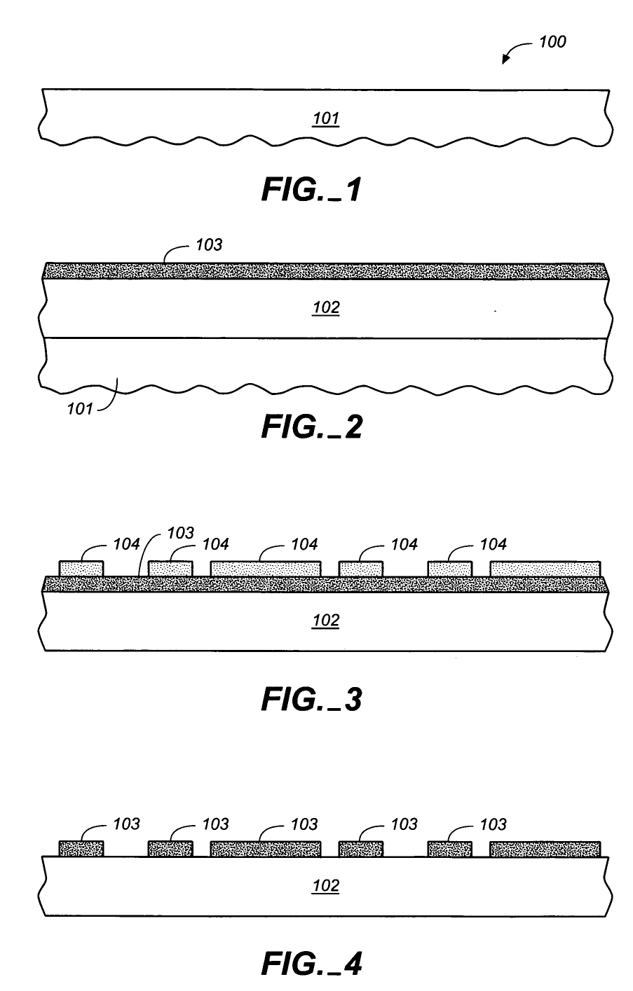

FIG. 1 is a simplified schematic depiction of a substrate structure 100 in the process of fabrication in accordance with an embodiment of the invention. In one depicted embodiment, a top portion of a substrate 101 suitable for implementation in accordance with the principles of the invention is shown. The inventors point out that the principles of the invention can be applied to a wide range of substrates. In one embodiment, the substrate can be a printed circuit board (PCB). In other implementations, suitable substrates 101 can be semiconductor substrates (e.g., semiconductor wafers). For example, the substrate 101 can be constructed of silicon or gallium arsenide (GaAs) or other materials known to those of ordinary skill in the art. SOI substrates or other commonly used substrates can be used. Additionally, the substrates can be used at various stages of processing. For example, the embodiments described herein can be applied to un-patterned substrates or substrates already having many layers of structures formed thereon. Although not limited to such, the depicted substrate 101 is described for ease of explanation as a silicon wafer. The depicted substrate 101 can be provided having many layers of structures already formed thereon. For example, the substrate can be formed having many levels of active circuit elements and/or electrical interconnect lines formed thereon. Such structures can include the lattice and bracing structures that are described in greater detail herein below.

Referring now to FIG. 2, the substrate has a first layer of thermal evaporation material 102 formed thereon. On top of the thermal evaporation material 102 is formed a layer of bracing material 103. The thermal evaporation material is a material that is capable of becoming gaseous at a relatively low temperature and then being evaporated from a surface upon heating. One suitable family of such materials includes polymers such as butylnorbornene and triethoxysilyl norbornene available from Unity Sacrificial Polymers, from B.F. Goodrich. Similar sacrificial polymer materials are also available from, for example, Dow Chemical. Such materials can be spin deposited onto the substrate 101 to a desired thickness. The inventors point out that other thermal evaporation materials having sufficient structural integrity after spin coating and satisfactory evaporation properties can be used. For example, materials having an evaporation temperature in the range of about 150° C. to about 400° C. are suitable. This is because temperatures much above 400° C. may have adverse effects on sensitive or reactive materials used in processing (e.g., copper). The layer of thermal evaporation material 102 can be formed to virtually any thickness dictated by the process engineer. Considerations such as the structural strength of the final structure and the aspect ratios of openings to be made in the layer of thermal evaporation material 102 can be considered along with other factors. Typically, thicknesses in the range of about 0.3 micron (μ) to about 4μ are employed with some embodiments using thicknesses in the range of about 0.3 micron (μ) to about 1μ also being used. After the formation of the first layer of thermal evaporation material 102 the material 102 can be planarized if desired. Typically a chemical mechanical polishing (CMP) process will be used.

After the first layer of thermal evaporation material 102 is formed a layer (or optionally several layers) of bracing material 103 is formed. This material will construct a resulting lattice structure and is generally chosen from among materials having suitable mechanical strengths. Thus, low-K dielectric materials like CORAL, Black Diamond, and SiLK are unsuitable bracing materials. Generally, materials having a hardness of greater than about 8 Mohn are preferred. A partial list of suitable bracing materials includes, but is not limited to, oxides of silicon (e.g. SiO₂), silicon oxycarbide materials, silicon carbide materials, silicon nitrides (SiₓN_{y}), silicon oxynitrides (SiₓO_{y}N_{z}), titanium nitrides (TiN), tantalum nitrides (TaN), as well as other structurally hard materials. These materials can be formed into a layer 103 of bracing material using any of a number of techniques known to those having ordinary skill in the art. For example, deposition could be used. If the layer 103 of bracing material is formed of SiO₂, for example, a TEOS deposition process can be used to form the layer 103 of bracing material on the thermal evaporation material 102. The layer 103 of bracing material is formed to a thickness that will result in sufficient mechanical strength in the final lattice structure. Thicker layers 103 of bracing material (or more layers of bracing material) will result in a stronger final lattice structure whereas thinner layers will not be as strong. In one example embodiment, a layer 103 of bracing material comprising SiO₂ can be formed to a thickness of in the range of about 200 Å (angstroms) to about 500 Å. In one embodiment, a SiO₂ layer 103 can be formed by deposition using CVD techniques. In one suitable example process a CVD machine, such as a Sequels deposition tool from Novellus of Santa Clara Calif. can be employed. In another one embodiment, a SiO₂ layer 103 can be formed by deposition using PVD techniques. One suitable process employs a PVD machine, such as an Endura 5500 manufactured by Applied Materials of Santa Clara, Calif. One example of a suitable process operates at a power in the range of about 10-100 kW and a pressure in the range of about 0.05 mTorr to about 5 mTorr. One preferred implementation uses a power of about 24 kW at about 1 mTorr.

As depicted in FIG. 3, the layer of bracing material 103 is then patterned with a photoimageable material layer 104. Typical photoimageable materials include photoresist materials. Commonly, such patterning is accomplished using photolithographic processes and methods known to those having ordinary skill in the art. These patterns are configured to create a set of openings where it is desired to remove the bracing material 103. This structure is then etched with an appropriate etch than can remove the layer 103 of bracing material.

FIG. 4 depicts a resultant pattern transfer onto the bracing material of layer 103. The depicted structure is shown after it has been defined, etched and the photoimageable material (e.g., photoresist) has been removed. This layer 103 of bracing material forms part of a resulting lattice support structure and can also serve as a hard mask for a damascene type process used to form subsequently formed recessed conductive structures. The depicted structure is shown with the photoresist material removed. This structure is again treated with thermal evaporation material to form a second layer 105 of thermal evaporation material. Typically, the second layer 105 is formed of the same thermal evaporation material as the first layer 102, although a different thermal evaporation material can be used if desired.

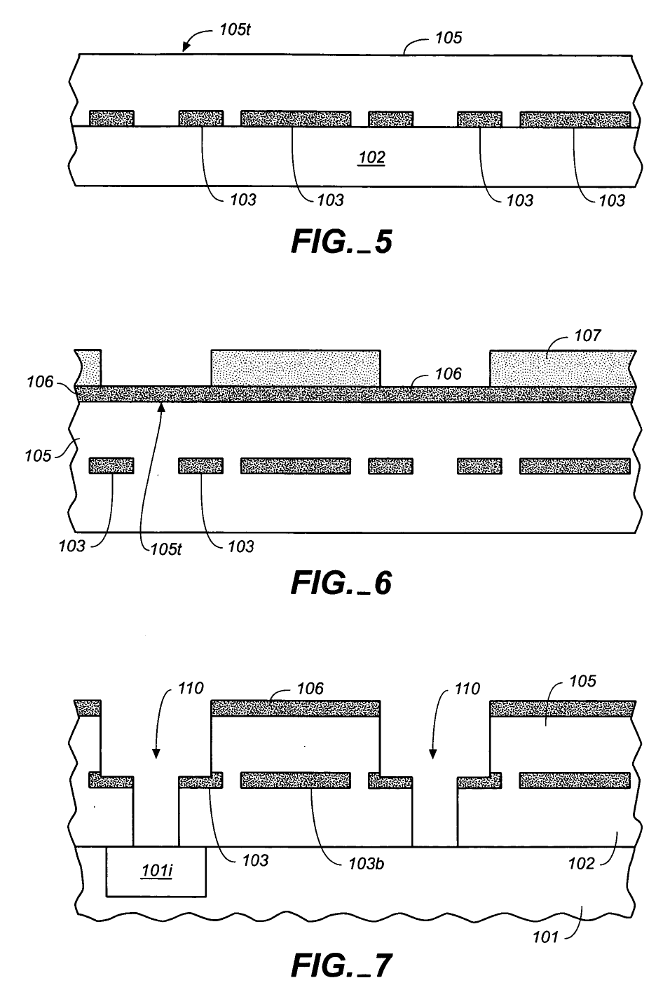

FIG. 5 shows a resulting structure after the formation of the second layer 105 of thermal evaporation material. The second layer is formed over the first layer 102 of thermal evaporation material and over the patterned bracing material 103. The second layer 105 of thermal evaporation material can be formed to virtually any thickness dictated by the process engineer. However, some embodiments require that the second layer 105 be formed thick enough so even in the presence of the underlying patterned bracing material 103 that the top surface 105t of the second layer 105 be substantially flat. Alternatively, embodiments can use thinner second layers 105 and use CMP to establish a substantially flat top surface 105t. Again, thicknesses typically range from about 0.3 micron (μ) to about 4μ, with some embodiments using thicknesses in the range of about 0.3 micron (μ) to about 1μ. After the formation of the second layer 105 of thermal evaporation material the second layer 105 can be planarized if desired.

In FIG. 6 a second layer 106 of bracing material is applied to the surface 105t of the second layer 105 of thermal evaporation material. As before, the second layer 106 of bracing material can form part of the resulting lattice structure and is generally chosen from among materials having suitable mechanical strengths. Again, the second layer 106 can be constructed of more than one layer of bracing material. Also again, materials having a hardness of greater than about 8 Mohn are preferred. Although not required, it is advantageous to form the second layer 106 of barrier material using the same materials as the first layer of bracing material 103 as this simplifies process flows. As before, suitable materials include, without limitation, oxides of silicon (e.g. SiO₂), silicon oxycarbide materials, silicon carbide materials, silicon nitrides (SiₓN_{y}), silicon oxynitrides (SiₓO_{y}N_{z}), titanium nitrides (TiN), tantalum nitrides (TaN), as well as other structurally hard materials. Similar to the first layer 103 of bracing material, the second layer 106 of bracing material can be formed using any of a number of techniques known to those having ordinary skill in the art. For example, although not limited to such, a deposition technique could be used. If the second layer 106 is formed of SiO₂, for example, a TEOS deposition process can be used. The second layer 106 of bracing material is also formed to a thickness that will result in sufficient mechanical strength in the final lattice structure. In the depicted example embodiment, a second layer 106 of bracing material comprising SiO₂ can be formed to a thickness of in the range of about 200 Å (angstroms) to about 500 Å. Additionally, the second layer 106 of bracing material is pattern masked with a photo-definable material (e.g., photoresist layer 107) configured to create a set of openings where it is desired to remove the second layer 106 of bracing material. Here the openings in the second layer 106 of bracing material can also be used to define a hard mask for a dual damascene process used to form recessed conductive structures. Additionally, a resultant pattern transfer onto the second layer 106 of bracing material can be used to define another layer of brace structures for supporting the resulting lattice support structure.

FIG. 7 shows the resultant structure after an etching process and the removal of the photoresist layer 107. In one implementation, a first etch chemistry is used to remove portions of the second layer 106 of bracing material. An etch chemistry selective to the second layer 106 of bracing material is preferably used to remove the second layer 106 of bracing material in the regions defined by the pattern mask. In one embodiment, a directional etch process can be used to remove the second layer 106. Commonly a reactive ion etch (RIE) process or low pressure plasma etching will be employed. In one process, a tool such as a Model 9400T Etching Machine available from Lam Research Corporation can be used to achieve satisfactory etching of the second layer 106. For example, in one embodiment, the following process parameters can be used. The etch can be conducted at a pressure of about 12 mTorr with a top electrode power of about 900 W (watts) and a bottom electrode power of about 150 W. Oxygen flow rates of about 15 SCCM, CF₄ flow rates of about 25 SCCM, and C₄F₈ flow rates of about 2 SCCM can be used to provide suitable etching of the layer 106. Once the desired degree of etching is performed on layer 106, a second etch chemistry, selective for the thermal evaporation material 102, 105, can be used to remove this material. This second etch is also typically accomplished using a directional anisotropic etch techniques. For example, a low pressure RIE process using an oxidizing chemistry can be used. One suitable etch chemistry is an oxygen containing plasma with a low concentration of fluorine plasma. For example, the process can employ an etch tool such as Lam Research Corporation's Model 9400T Etching Machine. Satisfactory etching of the thermal evaporation material 102, 105 can be achieved, in one example embodiment, using the following process parameters. Etching can be conducted at a pressure of about 5 mTorr with a top electrode power of about 900 W and a bottom electrode power of about 100 W. Oxygen flow rates of about 3 SCCM can be used with CF₄ flow rates of about 2 SCCM and C₄F₈ flow rates in the range of about 0.01 to about 1 SCCM to provide suitable etching of the thermal evaporation material 102, 105

Such etching continues until the underlying substrate 101 is reached. In the particular depicted embodiment, the etch can be performed until an underlying interconnect structure 101i is reached. This etch of the thermal evaporation material typically removes some material from the exposed first layer 103 of bracing material. It should be pointed out that the bracing material can be used to form “girders” 103b on a microscopic scale. These girders can be formed to span long distances. For example, in a semiconductor die, the girders can span substantial portion of the die. Additionally, although not depicted in the cross-section view of FIG. 7, the girders 103b can be constructed orthogonally (or any other transverse direction for that matter) from other girders in the substrate (not shown in this view). In the depicted embodiment, the etching process can be used to form a dual damascene opening 110 for via and interconnect formation.

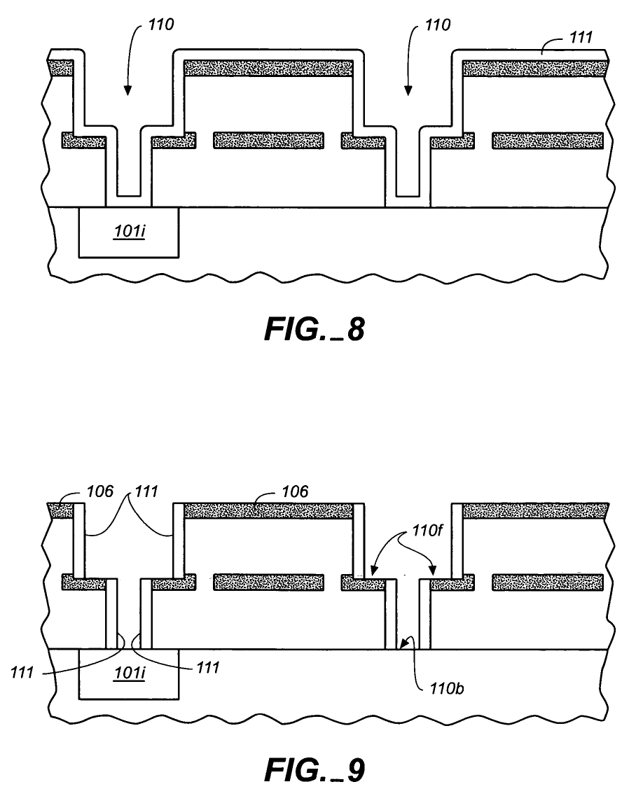

In FIG. 8 a third layer of bracing material 111 is applied to the surface. Typically, the third layer 111 is conformal to the surface and relatively thin. It is generally desirable to coat the walls of the openings 110 with the layer 111. As with the other layers of bracing material 103, 106, the third layer 111 of bracing material can form part of the resulting lattice structure. In the depicted embodiment, the third layer 111 can provide support for damascene structures to be formed in openings 110.

Again, the bracing material of the third layer 111 are generally chosen from among materials having suitable mechanical strengths. Again, materials having a hardness of greater than about 8 Mohn are preferred. Although not required, it is advantageous to form the third layer 111 of barrier material using the same materials as the first and second layers of bracing material 103, 106 as this simplifies process flows. As before, suitable materials include, without limitation, oxides of silicon (e.g. SiO₂), silicon oxycarbide materials, silicon carbide materials, silicon nitrides (SiₓN_{y}), silicon oxynitrides (SiₓO_{y}N_{z}), titanium nitrides (TiN), tantalum nitrides (TaN), as well as other structurally hard materials. As with the first and second layers 103, 106, the third layer 111 can be formed using any of a number of techniques known to those having ordinary skill in the art. For example, although not limited to such, a wide range of deposition techniques could be used. Examples include but are not limited to MOCVD, PVD, PECVD, CVD, ALD, and PEALD deposition techniques. If the third layer 111 is formed of SiO₂, for example, a TEOS deposition process can be used. Also, the principles of the invention are not confined to such SiO₂ deposition techniques as described above. Rather the full range of SiO₂ layer forming techniques known to those having ordinary skill in the art can be employed to construct suitable third layers 111 of SiO₂. The third layer 111 of bracing material is also formed to a thickness that will result in sufficient mechanical strength in the final lattice structure. In the depicted example embodiment, a third layer 111 of bracing material comprising SiO₂ can be formed to a thickness of in the range of about 200 Å (angstroms) to about 500 Å. Additionally, the thickness of the third layer 111 of bracing material is dependent on deposition parameters defined by the size and depth of the openings 110.

FIG. 9 depicts the substrate after another etch step. After the deposition of the third layer 111, if it is desirable to create a high quality electrical contact with the underlying interconnect 101i, material of the third layer 111 can be removed from the bottom 110b of the opening 110. In one embodiment, this can be accomplished using an anisotropic bottom etch process to remove the bracing material from the bottom 110b of the opening. Typically, this will remove some of the bracing material 111 from other flat portions 110f of the opening 110. However, the increased thickness of these regions (due to the layer formed at FIG. 8) leaves a substantial amount of bracing material present at the flat portions 110f of the opening 110. Any of a number of suitable anisotropic etch techniques known to those of ordinary skill can be used to remove the bracing material from the bottom 110b of the opening 110. Additionally, this bottom etch step can be used to remove any residues (e.g., oxides) from the top of the interconnect 101i in the region defined by the bottom of the opening. This structure is in readiness for the formation of a conductive material layer in the opening 110.

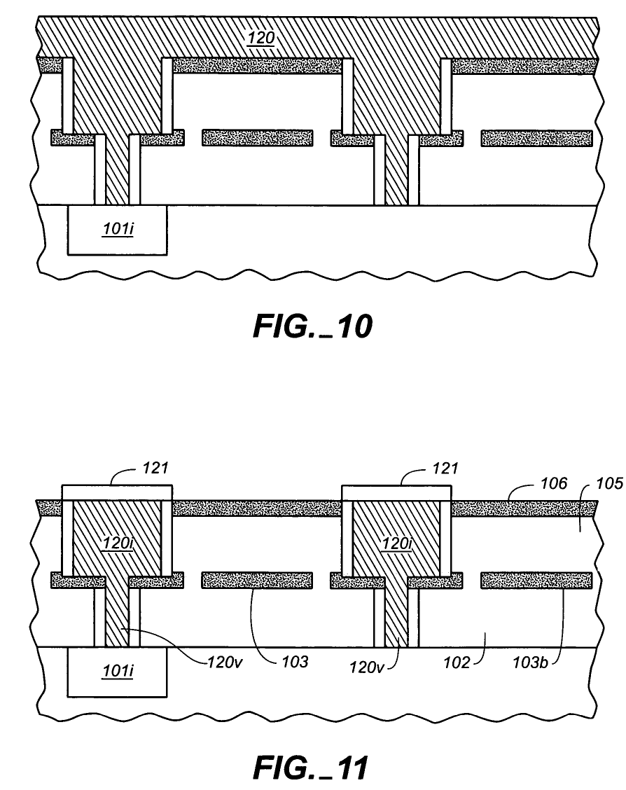

FIG. 10 shows the embodiment of FIG. 9 after the opening 110 has a conductive layer 120 formed thereon. The conductive layer 120 can be any conductive material. Examples include without limitation gold, copper, silver, aluminum or other suitable conductive materials and alloys. Methodologies for forming such conductive layers are well known in the art. For example, if the conductive material layer 120 includes copper. One or more barrier layers can be formed first using any of a number of techniques known in the art. Commonly a seed layer of copper material will then be formed, for example, using techniques known in the art. A bulk copper layer will then be formed using techniques known in the art. Typical examples being electroplating or electroless plating of the bulk copper layer onto the seed layer to complete the formation of the conductive layer 120.

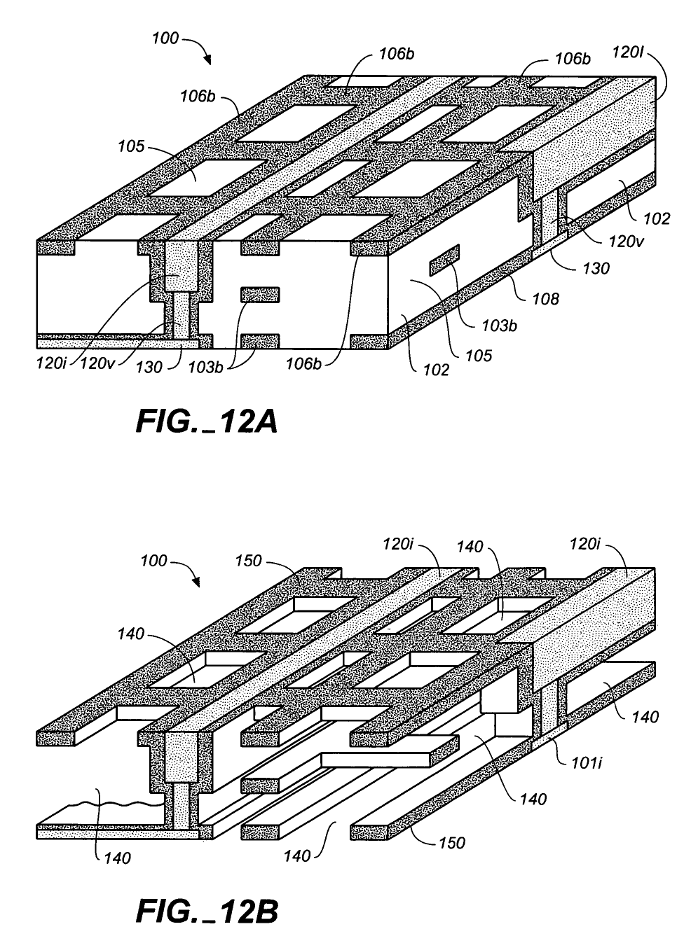

FIG. 11 depicts FIG. 10 after the formation of damascene interconnect 120i and via 120v structures are formed and after the planarization of the surface. Typically, the surface is planarized to complete the interconnects 120i and vias 120v at the same time the surface is planarized. Planarization can be accomplished using many different techniques known to those of ordinary skill in the art. In one example, standard CMP techniques can be used to establish a surface of the desired degree of planarity. At this time any portions of the second layer 106 of barrier material can be removed using standard etch techniques. For example, pattern masking and then etching away the portions of the second layer 106 of barrier material that the process engineer desires to remove. Also, a barrier layer can be formed on top of the interconnects 120i to form a capping layer 121, for example, to prevent copper diffusion out of the interconnects 120i. Many types of capping layers and methods of capping layer fabrication are known to those having ordinary skill in the art and can be readily employed here. Accordingly, one skilled in the art can employ many different techniques and materials to form the capping layers 121. Additionally, further layers of interconnect structures and bracing materials can be formed on the surface of the embodiment depicted in FIG. 11 to form a multi-layer lattice of bracing structures. The inventors point out that the conductive structures (e.g., 101i, 120i, 120v) can be annealed in accordance with a standard process flow using any of a number of annealing processes known to those having ordinary skill in the art. Alternatively, the annealing processes can be performed later.

FIG. 12A is a perspective schematic depiction of a substrate structure 101 in accordance with the principles of the invention. The simplified view of FIG. 12A shows the formed interconnect lines, vias, and lattice structure of bracing material. Example interconnect structures 120i are shown in conjunction with the via structures 120v that connect, for example, with and underlying conductive structure 130. Additionally, the layers of thermal evaporation material 102 and 105 are shown. Layers 103, 106 of bracing material are also shown. Additionally, another layer 108 of bracing material is shown. It can be seen that a criss-crossed pattern of the layers 103, 106 of bracing material define a network of bracing girders 103b, 106b that characterize a lattice structure supporting the structure 100 and in particular supporting the interconnects 120i and vias 120v. Although the girders 103b, 106b are depicted as intersecting each other along a common horizontal plane perpendicular to each other, this need not be the case. Girder 103b, 106b frameworks can intersect at any transverse orientation with some girders defining vertically oriented “towers” and other girders defining intersecting structures configured in any direction.

In one embodiment, at this point the structure 100 is subjected to a thermal evaporation process to remove the thermal evaporation material 102, 105 to define regions of extreme low-K dielectric (K values of less than about 2) space between the electrically conductive structures. For example, the structure can be heated at a temperature in the range of between 150° C. and 400° C. to effect satisfactory evaporation of the thermal evaporation material. Such space can be filled with the gases ambient in an evaporation chamber. Such gases are preferably substantially inert. Examples include, but are not limited to, air, argon, nitrogen, and many other materials known to those having ordinary skill in the art. These materials will define a space of extreme low-K in the regions evacuated by the evaporated thermal evaporation material. Alternatively, the evaporation process can be performed in vacuum or near vacuum conditions so that the regions of extreme low-K defined by the space previously occupied by the thermal evaporation material are now substantially vacuum. This also defines an extreme low-K dielectric space between the electrically conductive structures. Optionally, after the thermal evaporation material has been evaporated the structure can be treated with oxygen to remove carbon residue remaining from the evaporation of the thermal evaporation material. In one implementation the structure 100 can be treated with an oxygen plasma to remove the carbon residue.

FIG. 12B is a simplified schematic view of the structure of FIG. 12A after the thermal evaporation material has been evaporated. The extreme low-K space 140 lies throughout the structure 100 providing enhanced low-K dielectric properties. In particular the extreme low-K spaces 140 are defined between conductive layers and interconnects 120i. An array of girders constructed of bracing material defines a lattice structure 150 that lends considerable strength to the structure 100. Thus, through implementations of the invention, high strength and very low-K properties can be achieved. For example, such lattice structures 150 can comprise an integrated structure having aggregate hardnesses on the order of 10 Mohn or more. Such strength is useful for all circuit bearing structures, but is particularly usefully in semiconductor circuit structures.

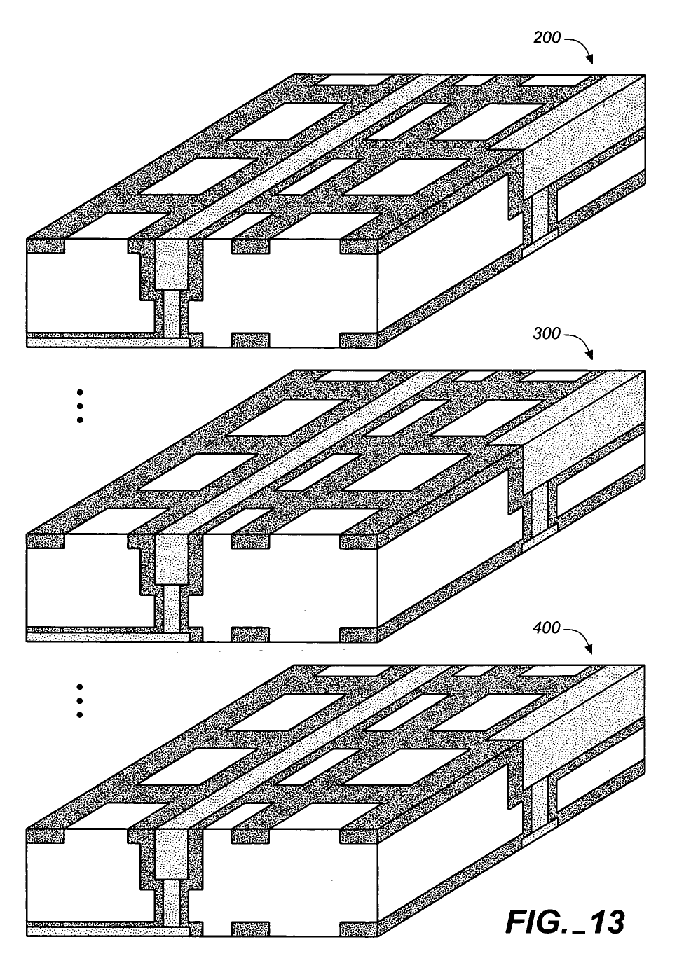

FIG. 13 is a simplified exploded schematic view of an embodiment of the invention having several levels 200, 300, 400 of via, interconnect and lattice structure. Layers of isolation or capping materials (not shown) can be used to prevent the various electrical connection s from shorting into one another. Typically, the levels are formed one on top of another until the desired number of levels is formed. This type of structure is believed to have less incidence of cracking and be stronger than structures formed using ordinary low-K dielectrics. Additionally, the lattices of each level can be interconnected with those of adjacent levels to achieve even greater strength. Additionally, in some embodiments the entire multilevel structure can be formed and completed. Then, once completed, all of the thermal evaporation material can be removed at once in a single evaporation process. Also, said annealing of the various layers (e.g., the copper layer) can be achieved in a single anneal step to anneal layers at once. Also, if desired the anneal and evaporation steps can be combined. Also, after such evaporation steps, the multi-layer structure can be treated with oxygen (e.g., treated with an oxygen plasma) to remove carbon residue from the extreme low-K spaces.

The present invention has been particularly shown and described with respect to certain preferred embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Other embodiments and variations to the depicted embodiments will be apparent to those skilled in the art and may be made without departing from the spirit and scope of the invention as defined in the following claims. Further, reference in the claims to an element in the singular is not intended to mean “one and only one” unless explicitly stated, but rather, “one or more”. Furthermore, the embodiments illustratively disclosed herein can be practiced without any element which is not specifically disclosed herein.

We claim:

1. An extreme low-K circuit structure comprising:
a substrate;
a plurality of electrically conductive structures; and
a lattice structure of bracing material configured to support the plurality of electrically conductive structures on the substrate and define regions of extreme low-K dielectric space between the plurality of electrically conductive structures.

2. The extreme low-K circuit structure of claim 1 wherein the lattice structure encases at least a portion of the plurality of electrically conductive structures.

3. The extreme low-K circuit structure of claim 1 wherein the plurality of electrically conductive structures include interconnect lines.

4. The extreme low-K circuit structure of claim 1 wherein the plurality of electrically conductive structures include conductive via structures.

5. The extreme low-K circuit structure of claim 1 wherein the plurality of electrically conductive structures include conductive via structures and interconnect lines and wherein said via structures electrically connect said interconnect lines.

6. The extreme low-K circuit structure of claim 1 wherein the substrate comprises a printed circuit board.

7. The extreme low-K circuit structure of claim 1 wherein the substrate comprises a semiconductor wafer capable of having integrated circuit dies formed thereon.

8. The extreme low-K circuit structure of claim 7 wherein
the substrate includes a first brace structure and wherein further brace structures are formed on the first brace structure of the substrate and are configured to define regions of low-K dielectric space between another plurality of electrically conductive structures.

9. The extreme low-K circuit structure of claim 1 wherein
the regions of extreme low-K dielectric space are substantially filled with air.

10. The extreme low-K circuit structure of claim 1 wherein
the regions of extreme low-K dielectric space are substantially vacuum filled.

11. The extreme low-K circuit structure of claim 1 wherein
the regions of extreme low-K dielectric space defined by the lattice structure define regions having a dielectric constant of less than two.

12. The extreme low-K circuit structure of claim 1 wherein
bracing materials used to form the lattice structure have a hardness of at least about eight (8) Mohn.

13. The extreme low-K circuit structure of claim 1 wherein
the lattice structure is configured to have an aggregate hardness of at least about ten (10) Mohn.

14. The extreme low-K circuit structure of claim 1 wherein the plurality of electrically conductive structures comprise a multi-layer electrically conductive layer; and
wherein the lattice structure comprises a multi-layer lattice structure configured to support the plurality of electrically conductive structures on the substrate and define regions of extreme low-K dielectric space between the plurality of electrically conductive structures.

15. An integrated circuit die having the extreme low-K circuit structure of claim 1 formed thereon.

16. An semiconductor wafer having a plurality of the extreme low-K circuit structures of claim 1 formed thereon.

17. A method of forming an extreme low-K circuit structure comprising:
providing a substrate;
forming a layer of thermally evaporatable material on the substrate;
patterning the thermally evaporatable material to receive bracing material;
forming a layer of bracing material on portions of the substrate and on portions of the thermally evaporatable material;
forming a plurality of electrically conductive structures on the bracing material; and
removing the thermally evaporatable material to form a lattice structure of bracing material that defines regions of low-K dielectric space between the plurality of electrically conductive structures.

18. The method of claim 17 wherein comprising:
patterning the thermally evaporatable material comprises forming a pattern of openings in the thermally evaporatable material;
wherein forming a layer of bracing material on portions of the thermally evaporatable material includes forming a layer of bracing material in said openings; and
wherein forming a plurality of electrically conductive structures includes introducing conductive material into the openings formed in the thermally evaporatable material.

19. The method of claim 17 wherein forming a layer of bracing material comprises forming a layer of bracing material having a hardness of at least about 8 Mohn.

20. The method of claim 17 wherein providing a substrate comprises providing a printed circuit board substrate.

21. The method of claim 17 wherein providing a substrate comprises providing a semiconductor wafer as a substrate.

22. The method of claim 19 wherein forming a layer of bracing material comprises increasing the thickness of the layer of bracing material in order to increase the strength of the resulting lattice structure.

23. The method of claim 17 wherein forming a layer of bracing material comprises forming a layer of bracing material that includes an oxide of silicon.

24. A method of forming an extreme low-K circuit structure wherein, after the plurality of electrically conductive structures are formed on the bracing material, further operations are performed, the further operations include:
forming a second layer of thermally evaporatable material on the substrate;
patterning the second layer of thermally evaporatable material to receive a second layer of bracing material;
forming a second layer of bracing material on portions of the second layer of thermally evaporatable material;
forming a second plurality of electrically conductive structures on the second layer of bracing material; and
removing, at the same time, both the layers of thermally evaporatable material to form a multiple layer lattice structure of bracing material that defines regions of low-K dielectric space between the electrically conductive structures.
